(19) United States
(12) Patent Application Publication
(10) Pub. No.: US 2024/0215305 A1
(43) Pub. Date: Jun. 27, 2024

(54) DISPLAY DEVICE AND METHOD OF MANUFACTURING THE SAME

(71) Applicant: Samsung Display Co., LTD., Yongin-si (KR)

(72) Inventors: Hyun Eok SHIN, Yongin-si (KR); Joon Yong PARK, Yongin-si (KR)

(21) Appl. No.: 18/375,670

(22) Filed: Oct. 2, 2023

(30) Foreign Application Priority Data
Dec. 23, 2022 (KR) 10-2022-0183416
Apr. 17, 2023 (KR) 10-2023-0050149

(51) Int. Cl. H10K 59/12; H10K 59/121; H10K 59/122; H10K 59/80; H10K 71/20; H10K 85/30

(52) U.S. Cl. CPC H10K 59/1201; H10K 59/121; H10K 59/122; H10K 59/873; H10K 71/231; H10K 85/371; H10K 2102/302

(57) ABSTRACT

A display device includes a first pixel electrode in a first emission area, an insulating layer covering an edge of the first pixel electrode, a first light-emitting layer on the first pixel electrode and the insulating layer, a first common electrode on the first light-emitting layer, a bank disposed on the insulating layer and surrounding the first emission area, and a first organic pattern surrounding the first emission area on the bank and including the same material as that of the first light-emitting layer. The bank includes a first bank contacting the first common electrode, a second bank disposed on the first bank and including a tip structure protruding toward the first emission area, and a third bank disposed on the second bank and having low reflection characteristics.

This application claims priority to Korean Patent Application No. 10-2022-0183416, filed on Dec. 23, 2022, and Korean Patent Application No. 10-2023-0050149, filed on Apr. 17, 2023, and all the benefits accruing therefrom under 35 U.S.C. § 119, the content of which in their entirety is herein incorporated by reference.

### BACKGROUND

### 1. Field

The disclosure relates to a display device and a method of manufacturing the same.

### 2. Description of the Related Art

As an information society develops, a demand for display devices for displaying images is being increased and diversified. For example, display devices are being applied to various electronic devices such as smartphones, digital cameras, laptop computers, navigation devices, and smart televisions. The display devices may be flat panel display devices such as liquid crystal display devices, field emission display devices, or organic light-emitting display devices. Among such flat panel display devices, a light-emitting display device may display an image without a backlight unit providing light to a display panel because each of pixels of the display panel includes light-emitting elements that may emit light by themselves.

### SUMMARY

Features of the disclosure provide a display device capable of decreasing external light reflectivity and improving display quality and a method of manufacturing the same.

However, features of the disclosure are not restricted to those set forth herein. The above and other features of the disclosure will become more apparent to one of ordinary skill in the art to which the disclosure pertains by referencing the detailed description of the disclosure given below.

In an embodiment, a display device includes a first pixel electrode disposed in a first emission area on a substrate, an insulating layer covering an edge of the first pixel electrode, a first light-emitting layer disposed on the first pixel electrode and the insulating layer, a first common electrode disposed on the first light-emitting layer, a bank disposed on the insulating layer and surrounding the first emission area, a first organic pattern surrounding the first emission area on the bank and including the same material as that of the first light-emitting layer, and a first electrode pattern surrounding the first emission area on the first organic pattern and including the same material as that of the first common electrode. The bank includes a first bank disposed on the insulating layer and in contact with the first common electrode, a second bank disposed on the first bank and including a tip structure protruding toward the first emission area to separate the first common electrode and the first electrode pattern from each other, and a third bank disposed on the second bank and having relatively low reflection characteristics.

In an embodiment, the third bank may include copper (Cu) alloy oxide or copper oxide (CuOx).

In an embodiment, the copper (Cu) alloy oxide may be copper-magnesium-aluminum oxide (CuMgAlOx).

In an embodiment, the first bank may include a copper (Cu) alloy, and the second bank may include titanium (Ti).

In an embodiment, the copper (Cu) alloy may be copper-magnesium-aluminum (CuMgAl).

In an embodiment, a composition ratio of copper (Cu) in the copper-magnesium-aluminum (CuMgAl) may be 90 at % or more.

In an embodiment, a side surface of the first bank may be recessed inward from a side surface of the second bank.

In an embodiment, the display device may further include a second pixel electrode disposed in a second emission area on the substrate, a second light-emitting layer disposed on the second pixel electrode, and a second common electrode disposed on the second light-emitting layer.

In an embodiment, the first and second common electrodes may be electrically connected to each other through the first bank.

In an embodiment, the display device may further include a second organic pattern surrounding the second emission area on the first electrode pattern and including the same material as that of the second light-emitting layer, and a second electrode pattern surrounding the second emission area on the second organic pattern and including the same material as that of the second common electrode.

In an embodiment, a method of manufacturing a display device includes forming first and second pixel electrodes on a substrate, stacking a sacrificial layer, an insulating layer, a first bank, a second bank, and a bank material on the first and second pixel electrodes, forming a third bank having relatively low reflection characteristics by performing a heat treatment process on the bank material, etching the third bank, the second bank, and the first bank so that a side surface of the second bank includes a tip structure protruding from a side surface of the first bank, exposing the first pixel electrode by etching the insulating layer and the sacrificial layer, and forming a first light-emitting layer on the first pixel electrode and forming a first organic pattern on the third bank.

In an embodiment, the bank material may include a copper (Cu) alloy, and the copper (Cu) alloy may be oxidized and changed into copper (Cu) alloy oxide through the heat treatment process.

In an embodiment, the bank material may include pure copper, and the pure copper may be oxidized and changed into copper oxide (CuOx) through the heat treatment process.

In an embodiment, the first bank may include a copper (Cu) alloy, and the second bank may include titanium (Ti).

In an embodiment, the copper (Cu) alloy may include copper-magnesium-aluminum (CuMgAl), and a composition ratio of copper (Cu) in the copper-magnesium-aluminum (CuMgAl) may be 90 at % or more.

In an embodiment, the etching the third bank, the second bank, and the first bank may include etching the side surface of the first bank more than the side surface of the second bank to form the protruding tip structure of the second bank.

In an embodiment, the forming the first light-emitting layer and the first organic pattern may include cutting an organic material deposited on the substrate by a tip of the second bank to separate the organic material into the first light-emitting layer and the first organic pattern.

In an embodiment, the method of manufacturing a display device may further include forming a first common electrode on the first light-emitting layer and forming a first electrode pattern on the first organic pattern, and forming a capping layer on the first common electrode and forming a first capping pattern on the first electrode pattern.

In an embodiment, the forming the first common electrode and the first electrode pattern may include cutting a metal material deposited on the substrate by a tip of the second bank to separate the metal material into the first common electrode and the first electrode pattern.

In an embodiment, the forming the capping layer and the first capping pattern may include cutting an inorganic material deposited on the substrate by a tip of the second bank to separate the inorganic material into the capping layer and the first capping pattern.

With a display device and a method of manufacturing the same in embodiments, the display device may decrease external light reflectivity and improve display quality by including a first bank having an excellent electrical conductivity and adhesive force, a second bank having relatively high heat blocking performance, and a third bank having relatively low reflection characteristics.

The effects of the disclosure are not limited to the aforementioned effects, and various other effects are included in the specification.

### BRIEF DESCRIPTION OF THE DRAWINGS

The above and other features and features of the disclosure will become more apparent by describing in detail embodiments thereof with reference to the attached drawings, in which:

FIG. 1 is a perspective view illustrating an embodiment of a display device:

FIG. 2 is a cross-sectional view illustrating an embodiment of the display device;

FIG. 3 is a plan view illustrating an embodiment of a display unit of the display device:

FIG. 4 is a cross-sectional view illustrating an embodiment of a portion of the display device:

FIG. 5 is an enlarged view of area A1 of FIG. 4; and

FIGS. 6 to 15 are cross-sectional views illustrating an embodiment of processes of manufacturing the display device.

### DETAILED DESCRIPTION

In the following description, for the purposes of explanation, numerous specific details are set forth in order to provide a thorough understanding of various embodiments or implementations of the disclosure. As used herein “embodiments” and “implementations” are interchangeable words that are non-limiting embodiments of devices or methods employing one or more of the disclosure disclosed herein. It is apparent, however, that various embodiments may be practiced without these specific details or with one or more equivalent arrangements. In other instances, structures and devices are shown in block diagram form in order to avoid unnecessarily obscuring various embodiments. Further, various embodiments may be different, but do not have to be exclusive nor limit the disclosure. For example, specific shapes, configurations, and characteristics of an embodiment may be used or implemented in other embodiments without departing from the disclosure.

Unless otherwise specified, the illustrated embodiments are to be understood as providing features of varying detail of some ways in which the disclosure may be implemented in practice. Therefore, unless otherwise specified, the features, components, modules, layers, films, panels, regions, and/or features, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Further, the X-axis, the Y-axis, and the Z-axis are not limited to three axes of a rectangular coordinate system, and thus the X-, Y-, and Z-axes, and may be interpreted in a broader sense. For example, the X-axis, the Y-axis, and the Z-axis may be perpendicular to one another, or may represent different directions that are not perpendicular to one another.

For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, ZZ, or the like. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise.

Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to cross-sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature, and the shapes of these regions may not reflect actual shapes of regions of a device and, as such, are not necessarily intended to be limiting.

As customary in the field, some embodiments are described and illustrated in the accompanying drawings in terms of functional blocks, units, parts, and/or modules. Those skilled in the art will appreciate that these blocks, units, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, parts, and/or modules being implemented by microprocessors or other similar hardware, they may be programmed and controlled using software (e.g., microcode) to perform various functions discussed herein and may optionally be driven by firmware and/or software. It is also contemplated that each block, unit, part, and/or module may be implemented by dedicated hardware, or as a combination of dedicated hardware to perform some functions and a processor (e.g., one or more programmed microprocessors and associated circuitry) to perform other functions. Also, each block, unit, part, and/or module of some embodiments may be physically separated into two or more interacting and discrete blocks, units, parts, and/or modules without departing from the scope of the disclosure. Further, the blocks, units, parts, and/or modules of some embodiments may be physically combined into more complex blocks, units, parts, and/or modules without departing from the scope of the disclosure.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within +30%, 20%, 10%, 5% of the stated value, for example.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, detailed embodiments of the disclosure is described with reference to the accompanying drawings.

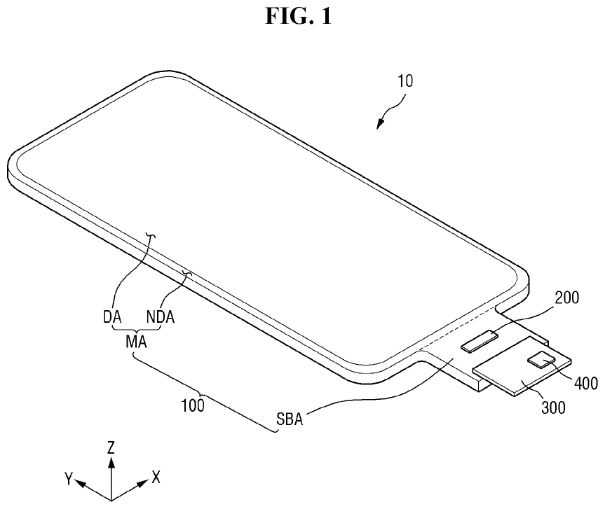

FIG. 1 is a perspective view illustrating an embodiment of a display device.

Referring to FIG. 1, a display device 10 may be applied to portable electronic devices such as mobile phones, smartphones, tablet personal computers (“PCs”), mobile communication terminals, electronic notebooks, electronic books, portable multimedia players (“PMPs”), navigation devices, and ultra mobile PCs (“UMPCs”). In an embodiment, the display device 10 may be applied as a display unit of televisions, laptop computers, monitors, billboards, or the Internet of Things (“IOTs”). In another embodiment, the display device 10 may be applied to wearable devices such as smart watches, watch phones, glasses-type displays, and head mounted displays (“HMDs”).

The display device 10 may have a shape similar to a quadrangular shape, e.g., rectangular shape, in a plan view. In an embodiment, the display device 10 may have a shape similar to a quadrangular shape, e.g., rectangular shape, in a plan view, having short sides in an X-axis direction and long sides in a Y-axis direction, for example. A corner where the short side in the X-axis direction and the long side in the Y-axis direction meet may be rounded with a predetermined curvature or may be right-angled. The shape of the display device 10 in a plan view is not limited to the quadrangular shape, e.g., rectangular shape, and may be a shape similar to other polygonal shapes, a circular shape, or an elliptical shape.

The display device 10 may include a display panel 100, a display driver 200, a circuit board 300, and a touch driver 400.

The display panel 100 may include a main area MA and a sub-area SBA.

The main area MA may include a display area DA including pixels displaying an image and a non-display area NDA disposed around the display area DA. The display area DA may emit light from a plurality of emission areas or a plurality of opening areas. In an embodiment, the display panel 100 may include pixel circuits including switching elements, a pixel defining film defining the emission areas or the opening areas, and self-light-emitting elements, for example.

In an embodiment, the self-light-emitting element may include at least one of an organic light-emitting diode (“LED”) including an organic light-emitting layer, a quantum dot LED including a quantum dot light-emitting layer, an inorganic LED including an inorganic semiconductor, and a micro LED, for example, but is not limited thereto.

The non-display area NDA may be an area outside the display area DA. The non-display area NDA may be defined as an edge area of the main area MA of the display panel 100. The non-display area NDA may include a gate driver (not illustrated) supplying gate signals to gate lines, and fan-out lines (not illustrated) connecting the display driver 200 and the display area DA to each other.

The sub-area SBA may extend from one side of the main area MA. The sub-area SBA may include a flexible material that may be bent, folded, and rolled. In an embodiment, when the sub-area SBA is bent, the sub-area SBA may overlap the main area MA in a thickness direction (Z-axis direction), for example. The sub-area SBA may include the display driver 200 and pad parts connected to the circuit board 300. In an alternative embodiment, the sub-area SBA may be omitted, and the display driver 200 and the pad parts may be disposed in the non-display area NDA.

The display driver 200 may output signals and voltages for driving the display panel 100. The display driver 200 may supply data voltages to data lines. The display driver 200 may supply source voltages to power lines and supply gate control signals to the gate driver. The display driver 200 may be formed as an integrated circuit (“IC”) and be disposed (e.g., mounted) on the display panel 100 in a chip on glass (“COG”) manner, a chip on plastic (“COP”) manner, or an ultrasonic bonding manner. In an embodiment, the display driver 200 may be disposed in the sub-area SBA, and may overlap the main area MA in the thickness direction (Z-axis direction) by bending of the sub-area SBA. In another embodiment, the display driver 200 may be disposed (e.g., mounted) on the circuit board 300.

The circuit board 300 may be attached onto the pad parts of the display panel 100 using an anisotropic conductive film (“ACF”). Lead lines of the circuit board 300 may be electrically connected to the pad parts of the display panel 100. The circuit board 300 may be a flexible printed circuit board, a printed circuit board, or a flexible film such as a chip on film.

The touch driver 400 may be disposed (e.g., mounted) on the circuit board 300. The touch driver 400 may be electrically connected to a touch sensing unit of the display panel 100. The touch driver 400 may supply touch driving signals to a plurality of touch electrodes of the touch sensing unit and sense change amounts in capacitance between the plurality of touch electrodes. In an embodiment, the touch driving signal may be a pulse signal having a predetermined frequency, for example. The touch driver 400 may decide whether or not an input has occurred and calculate input coordinates, based on the change amounts in capacitance between the plurality of touch electrodes. The touch driver 400 may be formed as an IC.

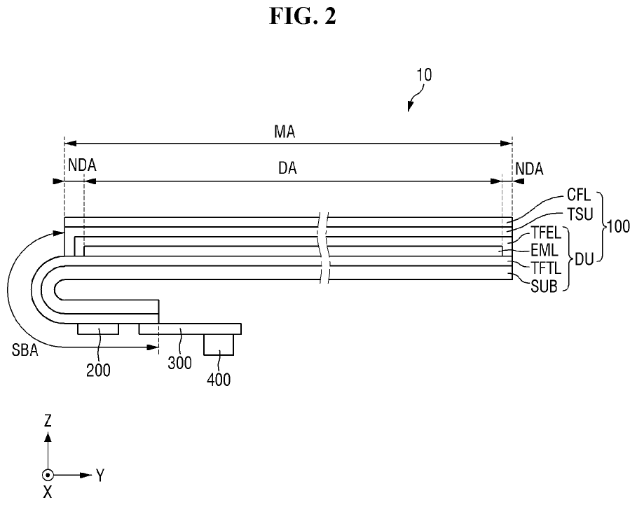

FIG. 2 is a cross-sectional view illustrating an embodiment of the display device. Referring to FIG. 2, the display panel 100 may include a display unit DU, a touch sensing unit TSU, and a color filter layer CFL. The display unit DU may include a substrate SUB, a thin film transistor layer TFTL, a light-emitting element layer EML, and an encapsulation layer TFEL.

The substrate SUB may be a base substrate or a base member. The substrate SUB may be a flexible substrate that may be bent, folded, and rolled. In an embodiment, the substrate SUB may include a polymer resin such as polyimide (“PI”), but is not limited thereto. In another embodiment, the substrate SUB may include a glass material or a metal material.

The thin film transistor layer TFTL may be disposed on the substrate SUB. The thin film transistor layer TFTL may include a plurality of thin film transistors constituting pixel circuits of pixels. The thin film transistor layer TFTL may further include gate lines, data lines, power lines, gate control lines, fan-out lines connecting the display driver 200 and the data lines to each other, and lead lines connecting the display driver 200 and the pad parts to each other. Each of the thin film transistors may include a semiconductor region, a source electrode, a drain electrode, and a gate electrode. In an embodiment, when the gate driver is formed on one side of the non-display area NDA of the display panel 100, the gate driver may include thin film transistors, for example.

The thin film transistor layer TFTL may be disposed in the display area DA, the non-display area NDA, and the sub-area SBA. The thin film transistors of each of the pixels, the gate lines, the data lines, and the power lines of the thin film transistor layer TFTL may be disposed in the display area DA. The gate control lines and the fan-out lines of the thin film transistor layer TFTL may be disposed in the non-display area NDA. The lead lines of the thin film transistor layer TFTL may be disposed in the sub-area SBA.

The light-emitting element layer EML may be disposed on the thin film transistor layer TFTL. The light-emitting element layer EML may include a plurality of light-emitting elements in which a pixel electrode, a light-emitting layer, and a common electrode are sequentially stacked to emit light and a pixel defining film defining pixels. The plurality of light-emitting elements of the light-emitting element layer EML may be disposed in the display area DA.

In an embodiment, the light-emitting layer may be an organic light-emitting layer including an organic material, for example. The light-emitting layer may include a hole transporting layer, an organic light-emitting layer, and an electron transporting layer. When the pixel electrode receives a predetermined voltage through the thin film transistor of the thin film transistor layer TFTL and the common electrode receives a cathode voltage, holes and electrons may move to the organic light-emitting layer through the hole transporting layer and the electron transporting layer, respectively, and may be combined with each other in the organic light-emitting layer to emit light. In an embodiment, the pixel electrode may be an anode electrode and the common electrode may be a cathode electrode, for example, but the disclosure is not limited thereto.

In another embodiment, the plurality of light-emitting elements may include quantum dot light-emitting diodes including a quantum dot light-emitting layer, inorganic light-emitting diodes including an inorganic semiconductor, or micro light-emitting diodes.

The encapsulation layer TFEL may cover an upper surface and side surfaces of the light-emitting element layer EML, and may protect the light-emitting element layer EML.

The encapsulation layer TFEL may include at least one inorganic film and at least one organic film for encapsulating the light-emitting element layer EML.

The touch sensing unit TSU may be disposed on the encapsulation layer TFEL. The touch sensing unit TSU may include a plurality of touch electrodes for sensing a user's touch in a capacitance manner and touch lines connecting the plurality of touch electrodes and the touch driver 400 to each other. In an embodiment, the touch sensing unit TSU may sense the user's touch in a mutual capacitance manner or a self-capacitance manner.

In another embodiment, the touch sensing unit TSU may be disposed on a separate substrate disposed on the display unit DU. In this case, the substrate supporting the touch sensing unit TSU may be a base member encapsulating the display unit DU.

The plurality of touch electrodes of the touch sensing unit TSU may be disposed in a touch sensor area overlapping the display area DA. The touch lines of the touch sensing unit TSU may be disposed in a touch peripheral area overlapping the non-display area NDA.

The color filter layer CFL may be disposed on the touch sensing unit TSU. The color filter layer CFL may include a plurality of color filters each corresponding to the plurality of emission areas. Each of the color filters may selectively transmit light of a predetermined wavelength therethrough and block or absorb light of other wavelengths. The color filter layer CFL may absorb some of light introduced from the outside of the display device 10 to reduce reflected light by external light. Accordingly, the color filter layer CFL may prevent distortion of colors due to external light reflection.

Since the color filter layer CFL is directly disposed on the touch sensing unit TSU, a separate substrate may not be desired for the color filter layer CFL in the display device 10. Accordingly, a thickness of the display device 10 may be relatively decreased.

The sub-area SBA of the display panel 100 may extend from one side of the main area MA. The sub-area SBA may include a flexible material that may be bent, folded, and rolled. In an embodiment, when the sub-area SBA is bent, the sub-area SBA may overlap the main area MA in the thickness direction (Z-axis direction), for example. The sub-area SBA may include the display driver 200 and the pad parts connected to a circuit board 300.

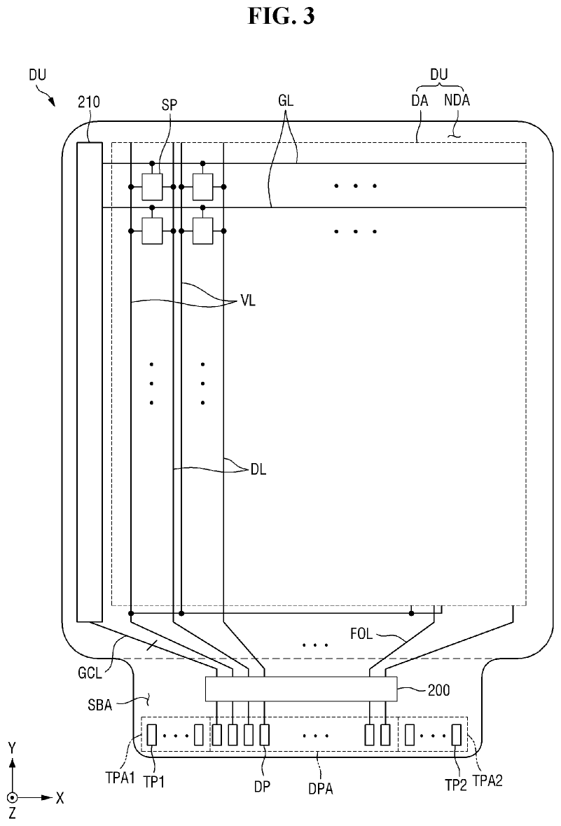

FIG. 3 is a plan view illustrating a display unit of the display device.

Referring to FIG. 3, the display unit DU may include a display area DA and a non-display area NDA.

The display area DA is an area displaying an image, and may be defined as a central area of the display panel 100. The display area DA may include a plurality of pixels SP, a plurality of gate lines GL, a plurality of data lines DL, and a plurality of power lines VL. Each of the plurality of pixels SP may be defined as a minimum unit outputting light.

The plurality of gate lines GL may supply gate signals received from a gate driver 210 to the plurality of pixels SP. The plurality of gate lines GL may extend in the X-axis direction, and may be spaced apart from each other in the Y-axis direction crossing the X-axis direction.

The plurality of data lines DL may supply data voltages received from the display driver 200 to the plurality of pixels SP. The plurality of data lines DL may extend in the Y-axis direction, and may be spaced apart from each other in the X-axis direction.

The plurality of power lines VL may supply source voltages received from the display driver 200 to the plurality of pixels SP. Here, the source voltage may be at least one of a driving voltage, an initialization voltage, a reference voltage, and a relatively low potential voltage. The plurality of power lines VL may extend in the Y-axis direction, and may be spaced apart from each other in the X-axis direction.

The non-display area NDA may surround the display area DA. The non-display area NDA may include the gate driver 210, fan-out lines FOL, and gate control lines GCL. The gate driver 210 may generate a plurality of gate signals based on gate control signals, and may sequentially supply the plurality of gate signals to the plurality of gate lines GL according to a set order.

The fan-out lines FOL may extend from the display driver 200 to the display area DA. The fan-out lines FOL may supply the data voltages received from the display driver 200 to the plurality of data lines DL.

The gate control lines GCL may extend from the display driver 200 to the gate driver 210. The gate control lines GCL may supply the gate control signals received from the display driver 200 to the gate driver 210.

The sub-area SBA may include the display driver 200, a display pad area DPA, and first and second touch pad areas TPA1 and TPA2.

The display driver 200 may output signals and voltages for driving the display panel 100 to the fan-out lines FOL. The display driver 200 may supply the data voltages to the data lines DL through the fan-out lines FOL. The data voltages may be supplied to the plurality of pixels SP, and may determine luminance of the plurality of pixels SP. The display driver 200 may supply the gate control signals to the gate driver 210 through the gate control lines GCL.

The display pad area DPA, the first touch pad area TPA1, and the second touch pad area TPA2 may be disposed at an edge of the sub-area SBA. The display pad area PA, the first touch pad area TPA1, and the second touch pad area TPA2 may be electrically connected to the circuit board 300 using a low-resistance and high-reliability material such as an anisotropic conductive film or a self assembly anisotropic conductive paste (“SAP”).

The display pad area DPA may include a plurality of display pad parts DP. The plurality of display pad parts DP may be electrically connected to a graphic system through the circuit board 300. The plurality of display pad parts DP may be connected to the circuit board 300 to receive digital video data, and may supply the digital video data to the display driver 200.

The first touch pad area TPA1 may be disposed on one side of the display pad area DPA, and may include a plurality of first touch pad parts TP1. The plurality of first touch pad parts TP1 may be electrically connected to the touch driver 400 disposed on the circuit board 300. The plurality of first touch pad parts TP1 may supply touch driving signals to a plurality of driving electrodes through a plurality of driving lines.

The second touch pad area TPA2 may be disposed on the other side of the display pad area DPA, and may include a plurality of second touch pad parts TP2. The plurality of second touch pad parts TP2 may be electrically connected to the touch driver 400 disposed on the circuit board 300. The touch driver 400 may receive touch sensing signals through a plurality of sensing lines connected to the plurality of second touch pad parts TP2, and may sense a change in mutual capacitance between the driving electrodes and the sensing electrodes.

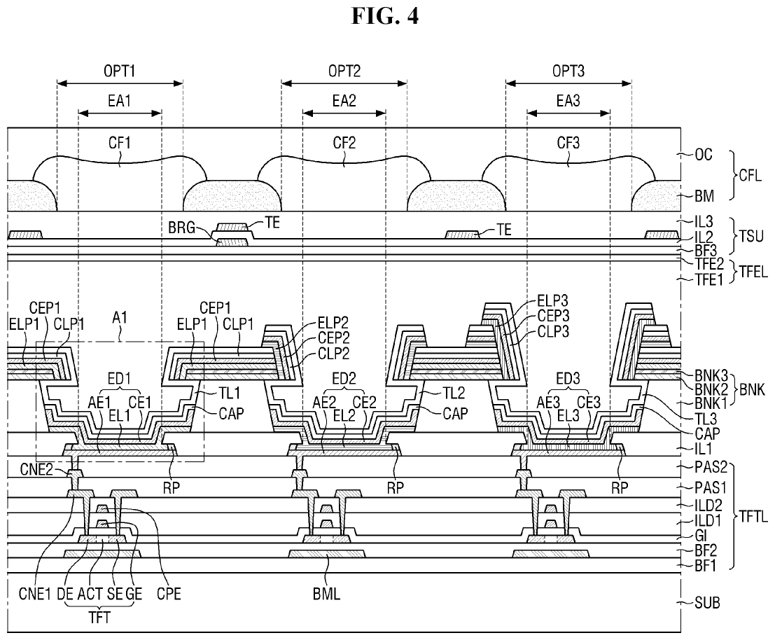

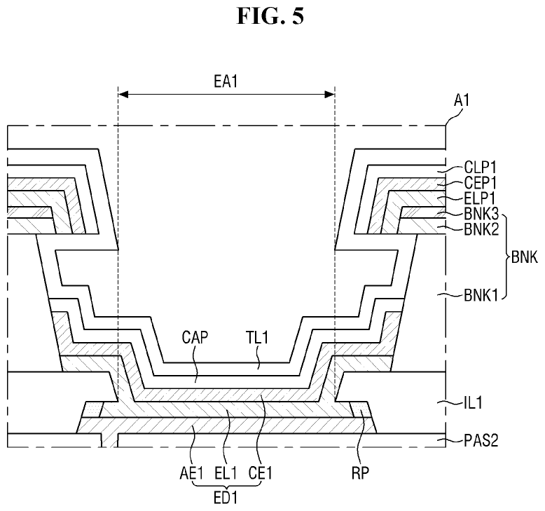

FIG. 4 is a cross-sectional view illustrating an embodiment of a portion of the display device in another embodiment, and FIG. 5 is an enlarged view of area A1 of FIG. 4.

Referring to FIGS. 2, 4 and 5, the display panel 100 may include a display unit DU, a touch sensing unit TSU, and a color filter layer CFL. The display unit DU may include a substrate SUB, a thin film transistor layer TFTL, a light-emitting element layer EML, and an encapsulation layer TFEL.

The substrate SUB may be a base substrate or a base member. The substrate SUB may be a flexible substrate that may be bent, folded, and rolled. In an embodiment, the substrate SUB may include a polymer resin such as polyimide (“PI”), but is not limited thereto. In another embodiment, the substrate SUB may include a glass material or a metal material.

The thin film transistor layer TFTL may include a first buffer layer BF1, a light-blocking layer BML, a second buffer layer BF2, thin film transistors TFT, a gate insulating layer GI, a first inter-insulating layer ILD1, capacitor electrodes CPE, a second inter-insulating layer ILD2, first connection electrodes CNE1, a first passivation layer PAS1, second connection electrodes CNE2, and a second passivation layer PAS2.

The first buffer layer BF1 may be disposed on the substrate SUB. The first buffer layer BF1 may include an inorganic film capable of preventing permeation of air or moisture. In an embodiment, the first buffer layer BF1 may include a plurality of inorganic films that are alternately stacked, for example.

The light-blocking layer BML may be disposed on the first buffer layer BF1. In an embodiment, the light-blocking layer BML may be formed as a single layer or multiple layers including any one of molybdenum (Mo), aluminum (Al), chromium (Cr), gold (Au), titanium (Ti), nickel (Ni), neodymium (Nd), and copper (Cu), or alloys thereof. In another embodiment, the light-blocking layer BML may be an organic film including a black pigment.

The second buffer layer BF2 may be disposed on the first buffer layer BF1 and the light-blocking layer BML. The second buffer layer BF2 may include an inorganic film capable of preventing permeation of air or moisture. In an embodiment, the second buffer layer BF2 may include a plurality of inorganic films that are alternately stacked, for example.

The thin film transistor TFT may be disposed on the second buffer layer BF2, and may constitute a pixel circuit of each of the plurality of pixels. In an embodiment, the thin film transistor TFT may be a driving transistor or a switching transistor of the pixel circuit. The thin film transistor TFT may include a semiconductor region ACT, a source electrode SE, a drain electrode DE, and a gate electrode GE, for example.

The semiconductor region ACT, the source electrode SE, and the drain electrode DE may be disposed on the second buffer layer BF2. The semiconductor region ACT, the source electrode SE, and the drain electrode DE may overlap the light-blocking layer BML in the thickness direction. The semiconductor region ACT may overlap the gate electrode GE in the thickness direction, and may be insulated from the gate electrode GE by the gate insulating layer GI. The source electrode SE and the drain electrode DE may be provided by making a material of the semiconductor region ACT conductors.

The gate electrode GE may be disposed on the gate insulating layer GI. The gate electrode GE may overlap the semiconductor region ACT with the gate insulating layer GI interposed therebetween.

The gate insulating layer GI may be disposed on the semiconductor region ACT, the source electrode SE, and the drain electrode DE. In an embodiment, the gate insulating layer GI may cover the semiconductor region ACT, the source electrode SE, the drain electrode DE, and the second buffer layer BF2, and may insulate the semiconductor region ACT and the gate electrode GE from each other, for example.

The first inter-insulating layer ILD1 may be disposed on the gate electrode GE and the gate insulating layer GI. The first inter-insulating layer ILD1 may insulate the gate electrode GE and the capacitor electrode CPE from each other.

The capacitor electrode CPE may be disposed on the first inter-insulating layer ILD1. The capacitor electrode CPE may overlap the gate electrode GE in the thickness direction. The capacitor electrode CPE and the gate electrode GE may form a capacitance.

The second inter-insulating layer ILD2 may be disposed on the capacitor electrode CPE and the first inter-insulating layer ILD1. The second inter-insulating layer ILD2 may insulate the capacitor electrode CPE and the first connection electrode CNE1 from each other.

The first connection electrode CNE1 may be disposed on the second inter-insulating layer ILD2. The first connection electrode CNE1 may electrically connect the drain electrode DE of the thin film transistor TFT and the second connection electrode CNE2 to each other. The first connection electrode CNE1 may be inserted into contact holes provided in the second inter-insulating layer ILD2, the first inter-insulating layer ILD1, and the gate insulating layer GI to contact the drain electrode DE of the thin film transistor TFT.

The first passivation layer PAS1 may be disposed on the first connection electrode CNE1 and the second inter-insulating layer ILD2. The first passivation layer PAS1 may protect the thin film transistor TFT. The first passivation layer PAS1 may insulate the first connection electrode CNE1 and the second connection electrode CNE2 from each other.

The second connection electrode CNE2 may be disposed on the first passivation layer PAS1. The second connection electrode CNE2 may electrically connect the first connection electrode CNE1 and a first pixel electrode AE1 of a first light-emitting element ED1 to each other. The second connection electrode CNE2 may be inserted into a contact hole provided in the first passivation layer PAS1 to contact the first connection electrode CNE1.

The second passivation layer PAS2 may be disposed on the second connection electrode CNE2 and the first passivation layer PAS1. The second passivation layer PAS2 may insulate the second connection electrode CNE2 and the first pixel electrode AE1 from each other.

The light-emitting element layer EML may be disposed on the thin film transistor layer TFTL. The light-emitting element layer EML may include first to third light-emitting elements ED1, ED2, and ED3, residual patterns RP, a first insulating layer IL1, capping layers CAP, a bank BNK, first to third organic patterns ELP1, ELP2, and ELP3, first to third electrode patterns CEP1, CEP2, and CEP3, first to third capping patterns CLP1, CLP2, and CLP3, and first to third inorganic layers TL1, TL2, and TL3.

The display device 10 may include a plurality of pixels arranged along a plurality of rows and columns in the display area DA. Each of the plurality of pixels may include first to third emission areas EA1, EA2, and EA3 defined by the bank BNK or the pixel defining film, and may emit light having a predetermined peak wavelength through the first to third emission areas EA1, EA2, and EA3. Each of the first to third emission areas EA1, EA2, and EA3 may be an area in which light generated by a light-emitting element of the display device 10 is emitted to the outside of the display device 10.

The first to third emission areas EA1, EA2, and EA3 may emit light having a predetermined peak wavelength to the outside of the display device 10. The first emission area EA1 may emit light of a first color, the second emission area EA2 may emit light of a second color, and the third emission area EA3 may emit light of a third color. In an embodiment, the light of the first color may be red light having a peak wavelength in the range of about 610 nanometer (nm) to about 650 nm, the light of the second color may be green light having a peak wavelength in the range of about 510 nm to about 550 nm, and the light of the third color may be blue light having a peak wavelength in the range of about 440 nm to about 480 nm, for example, but the disclosure is not limited thereto.

In an embodiment, an area of the third emission area EA3 may be greater than that of the first emission area EA1, and an area of the first emission area EA1 may be greater than that of the second emission area EA2, but the disclosure is not limited thereto. In another embodiment, an area of the first emission area EA1, an area of the second emission area EA2, and an area of the third emission area EA3 may be substantially the same as each other.

The first light-emitting element ED1 may be disposed in the first emission area EA1 on the thin film transistor layer TFTL. The first light-emitting element ED1 may include the first pixel electrode AE1, a first light-emitting layer EL1, and a first common electrode CE1. The second light-emitting element ED2 may be disposed in the second emission area EA2 on the thin film transistor layer TFTL. The second light-emitting element ED2 may include a second pixel electrode AE2, a second light-emitting layer EL2, and a second common electrode CE2. The third light-emitting element ED3 may be disposed in the third emission area EA3 on the thin film transistor layer TFTL. The third light-emitting element ED3 may include a third pixel electrode AE3, a third light-emitting layer EL3, and a third common electrode CE3.

The first pixel electrode AE1 may be disposed in the first emission area EA1 on the second passivation layer PAS2. The second pixel electrode AE2 may be disposed in the second emission area EA2 on the second passivation layer PAS2. The third pixel electrode AE3 may be disposed in the third emission area EA3 on the second passivation layer PAS2. Each of the first to third pixel electrodes AE1, AE2, and AE3 may be electrically connected to the drain electrode DE of the thin film transistor TFT through the first and second connection electrodes CNE1 and CNE2. The first to third pixel electrodes AE1, AE2, and AE3 may be insulated from each other by the first insulating layer IL1. In an embodiment, the first to third pixel electrodes AE1, AE2, and AE3 may include at least one of silver (Ag), copper (Cu), aluminum (Al), nickel (Ni), and lanthanum (La). In another embodiment, the first to third pixel electrodes AE1, AE2, and AE3 may include a material such as indium tin oxide (“ITO”), indium zinc oxide (“IZO”), or indium tin zinc oxide (“ITZO”). As still another example, the first to third pixel electrodes AE1, AE2, and AE3 may have a stacked structure such as ITO/Ag/ITO/, ITO/Ag/IZO, or ITO/Ag/ITZO/IZO.

The first insulating layer IL1 may be disposed on the second passivation layer PAS2 and the residual patterns RP. The first insulating layer IL1 may cover edges of the first to third pixel electrodes AE1, AE2, and AE3 and the residual patterns RP, and may expose portions of upper surfaces of the first to third pixel electrodes AE1, AE2, and AE3. In an embodiment, the first insulating layer IL1 may expose the first pixel electrode AE1 in the first emission area EA1, and the first light-emitting layer EL1 may be directly disposed on the first pixel electrode AE1, for example. The first insulating layer IL1 may include an inorganic insulating material. The first insulating layer IL1 may include at least one of a silicon nitride layer, a silicon oxynitride layer, a silicon oxide layer, a titanium oxide layer, an aluminum oxide layer, and an amorphous silicon layer, but is not limited thereto.

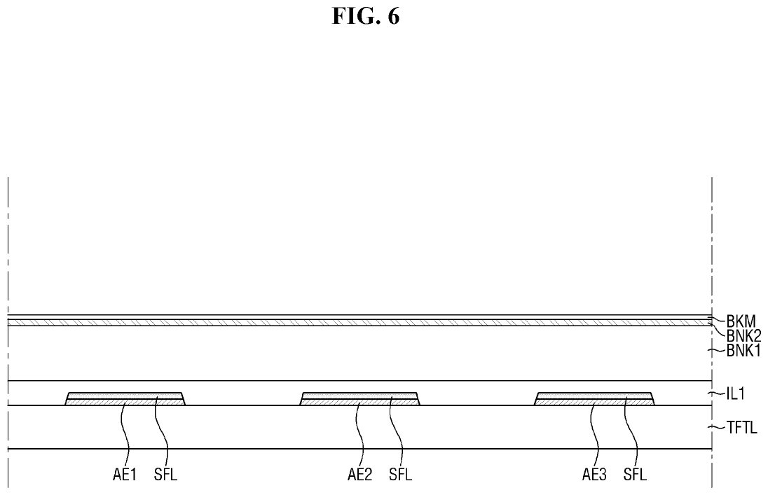

The residual pattern RP may be disposed on the edge of each of the first to third pixel electrodes AE1, AE2, and AE3. The first insulating layer IL1 may not be in direct contact with the upper surface of each of the first to third pixel electrodes AE1, AE2, and AE3 by the residual pattern RP. The residual patterns RP may be formed by removing a sacrificial layer SFL (refer to FIG. 6) disposed on the first to third pixel electrodes AE1, AE2, and AE3 in processes of manufacturing the display device 10.

The first to third light-emitting layers EL1, EL2, and EL3 may be organic light-emitting layers including an organic material, and may be formed on the first to third pixel electrodes AE1, AE2, and AE3, respectively, through a deposition process. In an embodiment, in a deposition process of the first to third light-emitting layers EL1, EL2, and EL3, the organic material may be deposited in a direction inclined from an upper surface of the substrate SUB, for example.

The first light-emitting layer EL1 may be disposed on the first pixel electrode AE1 in the first emission area EA1. A portion of the first light-emitting layer EL1 may be filled in a space surrounded by the first pixel electrode AE1, the residual pattern RP, and the first insulating layer IL1, and an opposite portion of the first light-emitting layer EL1 may cover a portion of an upper surface and side surfaces of the first insulating layer IL1. The second light-emitting layer EL2 may be disposed on the second pixel electrode AE2 in the second emission area EA2. A portion of the second light-emitting layer EL2 may be filled in a space surrounded by the second pixel electrode AE2, the residual pattern RP, and the first insulating layer IL1, and an opposite portion of the second light-emitting layer EL2 may cover a portion of the upper surface and the side surfaces of the first insulating layer IL1.

The third light-emitting layer EL3 may be disposed on the third pixel electrode AE3 in the third emission area EA3. A portion of the third light-emitting layer EL3 may be filled in a space surrounded by the third pixel electrode AE3, the residual pattern RP, and the first insulating layer IL1, and an opposite portion of the third light-emitting layer EL3 may cover a portion of the upper surface and the side surfaces of the first insulating layer IL1.

The first common electrode CE1 may be disposed on the first light-emitting layer EL1, the second common electrode CE2 may be disposed on the second light-emitting layer EL2, and the third common electrode CE3 may be disposed on the third light-emitting layer EL3. The first to third common electrodes CE1, CE2, and CE3 may include a transparent conductive material, and may transmit light generated in the first to third light-emitting layers EL1, EL2, and EL3 therethrough. The first to third common electrodes CE1, CE2, and CE3 may contact side surfaces of a first bank BNK1, and may be electrically connected to each other by the first bank BNK1. In an embodiment, the first to third common electrodes CE1, CE2, and CE3 may receive a common voltage or a relatively low potential voltage, for example.

The first pixel electrode AE1 may receive a voltage corresponding to a data voltage from the thin film transistor TFT, and the first common electrode CE1 may receive a common voltage or a cathode voltage. In this case, a potential difference is formed between the first pixel electrode AE1 and the first common electrode CE1, such that holes and electrons may move to the first light-emitting layer EL1 through a hole transporting layer and an electron transporting layer, respectively, and the first light-emitting layer EL1 may emit light.

The capping layers CAP may be disposed on the first to third common electrodes CE1, CE2, and CE3. The capping layers CAP may include an inorganic insulating material, and may cover the first to third light-emitting elements ED1, ED2, and ED3. The capping layers CAP may prevent the first to third light-emitting elements ED1, ED2, and ED3 from being damaged by external air. In an embodiment, the capping layer CAP may include at least one of a silicon nitride layer, a silicon oxynitride layer, a silicon oxide layer, a titanium oxide layer, an aluminum oxide layer, and an amorphous silicon layer, for example, but is not limited thereto.

The bank BNK may be disposed on the first insulating layer IL1 and define first to third emission areas EA1, EA2, and EA3. The bank BNK may surround the first to third emission areas EA1, EA2, and EA3 in a plan view. The bank BNK may overlap a light-blocking member BM of the color filter layer CFL. The bank BNK may include first to third banks BNK1, BNK2, and BNK3.

The first bank BNK1 may be disposed on the first insulating layer IL1, the second bank BNK2 may be disposed on the first bank BNK1, and the third bank BNK3 may be disposed on the second bank BNK2. A side surface of the first bank BNK1 may be recessed inward from a side surface of the second bank BNK2. The side surface of the second bank BNK2 protrudes from the side surface of the first bank BNK1 toward the first emission area EA1, and thus, the second bank BNK2 may include a protruding tip. Accordingly, a lower portion of the tip of the second bank BNK2 may have an undercut structure. A thickness of the first bank BNK1 may be greater than that of the second bank BNK2.

The first bank BNK1 may include a metal material different than that of the second and third banks BNK2 and BNK3. An etch rate of the first bank BNK1 may be different from an etch rate of the second and third banks BNK2 and BNK3. In an embodiment, in a wet etching process, the etch rate of the first bank BNK1 may be higher than the etch rate of the second and third banks BNK2 and BNK3, and the first bank BNK1 may be etched more than the second and third banks BNK2 and BNK3 in a process of forming the first to third emission areas EA1, EA2, and EA3, for example. Accordingly, shapes of the side surfaces of the first to third banks BNK1, BNK2, and BNK3 may be determined by a difference between the etch rates of the first to third banks BNK1, BNK2, and BNK3.

The first bank BNK1 may include a metal material having relatively high electrical conductivity. The first bank BNK1 may electrically connect between the first to third common electrodes CE1, CE2, and CE3 spaced apart from each other. The first bank BNK1 may include a copper (Cu) alloy. In an embodiment, the copper (Cu) alloy may be copper-magnesium-aluminum (CuMgAl), for example, but is not limited thereto. A composition ratio of copper (Cu) in copper-magnesium-aluminum (CuMgAl) may be about 90 at % or more, and a composition ratio of magnesium-aluminum (MgAl) in copper-magnesium-aluminum (CuMgAl) may be about 10 at % or less, but the disclosure is not limited thereto. Preferably, the composition ratio of copper (Cu) in copper-magnesium-aluminum (CuMgAl) may be about 90 at %, a composition ratio of magnesium (Mg) in copper-magnesium-aluminum (CuMgAl) may be about 3 at %, and a composition ratio of aluminum (Al) in copper-magnesium-aluminum (CuMgAl) may be about 7 at %. A composition ratio of copper-magnesium-aluminum (CuMgAl) may be easily designed and changed in order to prevent formation of an oxide film on a side surface or to enhance an adhesive force. Since the first bank BNK1 includes the copper (Cu) alloy, it is possible to prevent an oxide film from being formed on the side surface of the first bank BNK1, such that electrical conductivity of the first bank BNK1 may be stably maintained, and an adhesive force between the first bank BNK1 and the first insulating layer IL1 may be enhanced, such that a separate barrier layer may not be desired.

The second bank BNK2 may include a metal material having relatively high thermal blocking performance. The second bank BNK2 may include titanium (Ti), but is not limited thereto. The second bank BNK2 may block heat from being transferred to the first bank BNK1 in a heat treatment process of the third bank BNK3 to prevent the first bank BNK1 from being oxidized.

The third bank BNK3 may include a metal material having relatively low reflectivity. The third bank BNK3 may include copper (Cu) alloy oxide or copper oxide (CuOₓ). In an embodiment, the copper (Cu) alloy oxide may be copper-magnesium-aluminum oxide (CuMgAlOₓ), for example, but is not limited thereto. The thickness of the first bank BNK1 may be greater than that of the third bank BNK3, and the thickness of the third bank BNK3 may be greater than that of the second bank BNK2. The thickness of the first bank BNK1 may be about 6000 angstroms (Å), the thickness of the second bank BNK2 may be about 200 Å, and the thickness of the third bank BNK3 may be about 400 Å to about 500 Å, but the disclosure is not limited thereto.

The display device 10 may have a relatively low reflectivity in a region of visible light (about 550 nm) by including the third bank BNK3 having relatively low reflection characteristics. Accordingly, the display device 10 may decrease external light reflectivity and improve display quality.

The bank BNK may form the first to third emission areas EA1, EA2, and EA3 through a mask process, and each of the first to third light-emitting layers EL1, EL2, and EL3 may be formed in each of the first to third emission areas EA1, EA2, and EA3. When the mask process is performed, a structure for mounting a mask may be desired, and an excessively wide area of the non-display area NDA may be desired in order to control distribution of the mask process. Accordingly, when the mask process is minimized, the structure for mounting the mask may be omitted, and the area of the non-display area NDA for controlling the distribution may be minimized.

The first to third light-emitting elements ED1, ED2, and ED3 may be formed through deposition and etching processes rather than the mask process. Since the first bank BNK1 includes the metal material different than that of the second and third banks BNK2 and BNK3, an inner sidewall of the bank BNK may have a tip structure, and the display device 10 may include different layers individually formed in the first to third emission areas EA1, EA2, and EA3 through a deposition process. In an embodiment, the first light-emitting layer EL1 and the first organic pattern ELP1 may be deposited using the same organic material in a deposition process that does not use a mask, and may be cut and separated from each other by a tip formed on the inner sidewall of the bank BNK, for example. The first light-emitting layer EL1 may be disposed in the first emission area EA1, and the first organic pattern ELP1 may be disposed on the bank BNK between the first to third emission areas EA1, EA2, and EA3.

An organic material for forming the first light-emitting layer EL1 may be deposited on an entirety of the surface of the display device 10, and the organic material of the first light-emitting layer EL1 deposited in the second and third emission areas EA2 and EA3 may be removed. An organic material for forming the second light-emitting layer EL2 may be deposited on the entirety of the surface of the display device 10, and the organic material of the second light-emitting layer EL2 deposited in the first and third emission areas EA1 and EA3 may be removed. An organic material for forming the third light-emitting layer EL3 may be deposited on the entirety of the surface of the display device 10, and the organic material of the third light-emitting layer EL3 deposited in the first and second emission areas EA1 and EA2 may be removed. Accordingly, in the display device 10, different organic materials may be formed in the first to third emission areas EA1, EA2, and EA3 through the deposition and etching processes without using the mask process. In the display device 10, unnecessary processes are omitted, such that a manufacturing cost may be reduced, and an area of the non-display area NDA may be minimized.

The first organic pattern ELP1 may include the same organic material as that of the first light-emitting layer EL1 and may be disposed on the bank BNK. The first organic pattern ELP1 may cover side surfaces of the second and third banks BNK2 and BNK3 adjacent to the first emission area EA1. The first light-emitting layer EL1 and the first organic pattern ELP1 may be deposited in the same process and may be cut and separated from each other by the tip formed on the inner sidewall of the bank BNK. Accordingly, the first organic pattern ELP1 may be disposed on the bank BNK in an area other than the first to third emission areas EA1, EA2, and EA3.

The first electrode pattern CEP1 may include the same metal material as that of the first common electrode CE1 and may be disposed on the first organic pattern ELP1. The first electrode pattern CEP1 may cover side surfaces of the first organic pattern ELP1 adjacent to the first emission area EA1. The first common electrode CE1 and the first electrode pattern CEP1 may be deposited in the same process, but may be cut by the tip formed on the inner sidewall of the bank BNK. Accordingly, the first electrode pattern CEP1 may be disposed on the first organic pattern ELP1 in the area other than the first to third emission areas EA1, EA2, and EA3.

The first capping pattern CLP1 may include the same inorganic material as that of the capping layer CAP and may be disposed on the first electrode pattern CEP1. The first capping pattern CLP1 may cover side surfaces of the first electrode pattern CEP1 adjacent to the first emission area EA1. The capping layer CAP and the first capping pattern CLP1 may be deposited in the same process, but may be cut by the tip formed on the inner sidewall of the bank BNK. Accordingly, the first capping pattern CLP1 may be disposed on the first electrode pattern CEP1 in the area other than the first to third emission areas EA1, EA2, and EA3.

The first inorganic layer TL1 may be disposed on the capping layer CAP of the first emission area EA1 and the first capping pattern CLP1. The first inorganic layer TL1 may cover the side surfaces of the first bank BNK1 surrounding the first emission area EA1. The first inorganic layer TL1 may include an inorganic material to prevent oxygen or moisture from permeating into the first light-emitting element ED1. The first inorganic layer TL1 may be an inorganic encapsulation layer. In an embodiment, the first inorganic layer TL1 may include at least one of a silicon nitride layer, a silicon oxynitride layer, a silicon oxide layer, a titanium oxide layer, an aluminum oxide layer, and an amorphous silicon layer, for example, but is not limited thereto.

The second organic pattern ELP2 may include the same organic material as that of the second light-emitting layer EL2 and may be disposed on the first inorganic layer TL1. The second organic pattern ELP2 may cover side surfaces of the second and third banks BNK2 and BNK3, the first organic pattern ELP1, the first electrode pattern CEP1, the first capping pattern CLP1, and the first inorganic layer TL1 adjacent to the second emission area EA2. The second light-emitting layer EL2 and the second organic pattern ELP2 may be deposited in the same process, but may be cut by the tip formed on the inner sidewall of the bank BNK. Accordingly, the second organic pattern ELP2 may be disposed on the first inorganic layer TL1 in areas adjacent to the second and third emission areas EA2 and EA3.

The second electrode pattern CEP2 may include the same metal material as that of the second common electrode CE2 and may be disposed on the second organic pattern ELP2. The second electrode pattern CEP2 may cover side surfaces of the second organic pattern ELP2 adjacent to the second emission area EA2. The second common electrode CE2 and the second electrode pattern CEP2 may be deposited in the same process, but may be cut by the tip formed on the inner sidewall of the bank BNK. Accordingly, the second electrode pattern CEP2 may be disposed on the second organic pattern ELP2 in the areas adjacent to the second and third emission areas EA2 and EA3.

The second capping pattern CLP2 may include the same inorganic material as that of the capping layer CAP and may be disposed on the second electrode pattern CEP2. The second capping pattern CLP2 may cover side surfaces of the second electrode pattern CEP2 adjacent to the second emission area EA2. The capping layer CAP and the second capping pattern CLP2 may be deposited in the same process, but may be cut by the tip formed on the inner sidewall of the bank BNK. Accordingly, the second capping pattern CLP2 may be disposed on the second electrode pattern CEP2 in the areas adjacent to the second and third emission areas EA2 and EA3.

The second inorganic layer TL2 may be disposed on the capping layer CAP of the second emission area EA2 and the second capping pattern CLP2. The second inorganic layer TL2 may cover the side surfaces of the first bank BNK1 surrounding the second emission area EA2. The second inorganic layer TL2 may include an inorganic material to prevent oxygen or moisture from permeating into the second light-emitting element ED2. The second inorganic layer TL2 may be an inorganic encapsulation layer. In an embodiment, the second inorganic layer TL2 may include or consist of the material exemplified in the first inorganic layer TL1, for example.

The third organic pattern ELP3 may include the same organic material as that of the third light-emitting layer EL3 and may be disposed on the second inorganic layer TL2. The third organic pattern ELP3 may cover side surfaces of the second and third banks BNK2 and BNK3, the first organic pattern ELP1, the first electrode pattern CEP1, the first capping pattern CLP1, the first inorganic layer TL1, the second organic pattern ELP2, the second electrode pattern CEP2, the second capping pattern CLP2, and the second inorganic layer TL2 adjacent to the third emission area EA3. The third light-emitting layer EL3 and the third organic pattern ELP3 may be deposited in the same process, but may be cut by the tip formed on the inner sidewall of the bank BNK. Accordingly, the third organic pattern ELP3 may be disposed on the second inorganic layer TL2 in an area adjacent to the third emission area EA3.

The third electrode pattern CEP3 may include the same metal material as that of the third common electrode CE3 and may be disposed on the third organic pattern ELP3. The third electrode pattern CEP3 may cover side surfaces of the third organic pattern ELP3 adjacent to the third emission area EA3. The third common electrode CE3 and the third electrode pattern CEP3 may be deposited in the same process, but may be cut by the tip formed on the inner sidewall of the bank BNK. Accordingly, the third electrode pattern CEP3 may be disposed on the third organic pattern ELP3 in the area adjacent to the third emission area EA3.

The third capping pattern CLP3 may include the same inorganic material as that of the capping layer CAP and may be disposed on the third electrode pattern CEP3. The third capping pattern CLP3 may cover side surfaces of the third electrode pattern CEP3 adjacent to the third emission area EA3. The capping layer CAP and the third capping pattern CLP3 may be deposited in the same process, but may be cut by the tip formed on the inner sidewall of the bank BNK. Accordingly, the third capping pattern CLP3 may be disposed on the third electrode pattern CEP3 in the area adjacent to the third emission area EA3.

The third inorganic layer TL3 may be disposed on the capping layer CAP of the third emission area EA3 and the third capping pattern CLP3. The third inorganic layer TL3 may cover the side surfaces of the first bank BNK1 surrounding the third emission area EA3. The third inorganic layer TL3 may include an inorganic material to prevent oxygen or moisture from permeating into the third light-emitting element ED3. The third inorganic layer TL3 may be an inorganic encapsulation layer. In an embodiment, the third inorganic layer TL3 may include or consist of the material exemplified in the first inorganic layer TL1, for example.

The encapsulation layer TFEL may be disposed on the first to third inorganic layers TL1, TL2, and TL3 to cover the light-emitting element layer EML. The encapsulation layer TFEL may include first and second encapsulation layers TFEL and TFE2.

The first encapsulation layer TFE1 may be disposed on the first to third inorganic layers TL1, TL2, and TL3 to planarize an upper end of the light-emitting element layer EML. The first encapsulation layer TFE1 may include or consist of an organic material to protect the light-emitting element layer EML from foreign substances such as dust. In an embodiment, the first encapsulation layer TFE1 may include an organic film including an acrylic resin, an epoxy resin, a phenolic resin, a polyamide resin, a polyimide resin, or the like, for example. The first encapsulation layer TFE1 may be formed by curing a monomer or applying a polymer.

The second encapsulation layer TFE2 may be disposed on the first encapsulation layer TFE1. The second encapsulation layer TFE2 may include an inorganic material to prevent oxygen or moisture from permeating into the light-emitting element layer EML. In an embodiment, the second encapsulation layer TFE2 may include at least one of a silicon nitride layer, a silicon oxynitride layer, a silicon oxide layer, a titanium oxide layer, an aluminum oxide layer, and an amorphous silicon layer, for example, but is not limited thereto.

The touch sensing unit TSU may be disposed on the encapsulation layer TFEL. The touch sensing unit TSU may include a third buffer layer BF3, a bridge electrode BRG, a second insulating layer IL2, touch electrodes TE, and a third insulating layer IL3.

The third buffer layer BF3 may be disposed on the encapsulation layer TFEL. The third buffer layer BF3 may have insulating and optical functions. The third buffer layer BF3 may include at least one inorganic film. Optionally, the third buffer layer BF3 may be omitted.

The bridge electrode BRG may be disposed on the third buffer layer BF3. The bridge electrode BRG may be disposed at a different layer from the touch electrode TE to electrically connect adjacent touch electrodes TE to each other.

The second insulating layer IL2 may be disposed on the bridge electrode BRG and the third buffer layer BF3. The second insulating layer IL2 may have insulating and optical functions. In an embodiment, the second insulating layer IL2 may include at least one of a silicon nitride layer, a silicon oxynitride layer, a silicon oxide layer, a titanium oxide layer, an aluminum oxide layer, and an amorphous silicon layer, for example, but is not limited thereto.

The touch electrodes TE may be disposed on the second insulating layer IL2. The touch electrode TE may include a driving electrode and a sensing electrode, and may sense a change in mutual capacitance between the driving electrode and the sensing electrode. The touch electrode TE may not overlap the first to third emission areas EA1, EA2, and EA3. The touch electrode TE may be formed as a single layer including molybdenum (Mo), titanium (Ti), copper (Cu), aluminum (Al), or indium tin oxide (“ITO”) or be formed as a stacked structure (Ti/Al/Ti) of aluminum and titanium, a stacked structure (ITO/Al/ITO) of aluminum and ITO, an APC alloy, and a stacked structure (ITO/APC/ITO) of an APC alloy and ITO.

The third insulating layer IL3 may be disposed on the touch electrodes TE and the second insulating layer IL2. The third insulating layer IL3 may have insulating and optical functions. The third insulating layer IL3 may include or consist of the material exemplified in the second insulating layer IL2.

The color filter layer CFL may be disposed on the touch sensing unit TSU. The color filter layer CFL may include a light-blocking member BM, first to third color filters CF1, CF2, and CF3, and a planarization layer OC.

The light-blocking member BM may be disposed on the third insulating layer IL3 and may surround first to third optical areas OPT1, OPT2, and OPT3. The light-blocking member BM may overlap the touch electrodes TE. The light-blocking member BM may include a light absorbing material to prevent light reflection. In an embodiment, the light-blocking member BM may include an inorganic black pigment, an organic black pigment, or an organic blue pigment, for example. The inorganic black pigment may be a metal oxide such as carbon black or titanium black, the organic black pigment may include at least one of lactam black, perylene black, and aniline black, and the organic blue pigment may be C.I. Pigment Blue, but the disclosure is not limited thereto. The light-blocking member BM may prevent color mixing due to permeation of visible light between the first to third emission areas EA1, EA2, and EA3 to improve a color gamut of the display device 10.

The first color filter CF1 may be disposed in the first emission area EA1 on the third insulating layer IL3. The first color filter CF1 may be surrounded by the light-blocking member BM in a plan view. An edge of the first color filter CF1 may cover a portion of an upper surface of the light-blocking member BM, but is not limited thereto. The first color filter CF1 may selectively transmit the light of the first color (e.g., the red light) therethrough and block or absorb the light of the second color (e.g., the green light) and the light of the third color (e.g., the blue light). In an embodiment, the first color filter CF1 may be a red color filter and include a red colorant, for example.

The second color filter CF2 may be disposed in the second emission area EA2 on the third insulating layer IL3. The second color filter CF2 may be surrounded by the light-blocking member BM in a plan view: An edge of the second color filter CF2 may cover a portion of the upper surface of the light-blocking member BM, but is not limited thereto. The second color filter CF2 may selectively transmit the light of the second color (e.g., the green light) therethrough and block or absorb the light of the first color (e.g., the red light) and the light of the third color (e.g., the blue light). In an embodiment, the second color filter CF2 may be a green color filter and include a green colorant, for example.

The third color filter CF3 may be disposed in the third emission area EA3 on the third insulating layer IL3. The third color filter CF3 may be surrounded by the light-blocking member BM in a plan view: An edge of the third color filter CF3 may cover a portion of the upper surface of the light-blocking member BM, but is not limited thereto. The third color filter CF3 may selectively transmit the light of the third color (e.g., the blue light) therethrough and block or absorb the light of the first color (e.g., the red light) and the light of the second color (e.g., the green light). In an embodiment, the third color filter CF3 may be a blue color filter and include a blue colorant, for example.

The first to third color filters CF1, CF2, and CF3 may absorb a portion of light introduced from the outside of the display device 10 to reduce reflected light due to external light. Accordingly, the first to third color filters CF1, CF2, and CF3 may prevent distortion of colors due to external light reflection.

The planarization layer OC may be disposed on the light-blocking member BM and the first to third color filters CF1, CF2, and CF3. The planarization layer OC may planarize an upper end of the color filter layer CFL. In an embodiment, the planarization layer OC may include an organic insulating material, for example.

FIGS. 6 to 15 are cross-sectional views illustrating an embodiment of processes of manufacturing the display device.

In FIG. 6, the first to third pixel electrodes AE1, AE2, and AE3 may be spaced apart from each other on the thin film transistor layer TFTL. The first to third pixel electrodes AE1, AE2, and AE3 may include at least one of silver (Ag), copper (Cu), aluminum (Al), nickel (Ni), and lanthanum (La). In another embodiment, the first to third pixel electrodes AE1, AE2, and AE3 may include a material such as indium tin oxide (“ITO”), indium zinc oxide (“IZO”), or indium tin zinc oxide (“ITZO”). As still another example, the first to third pixel electrodes AE1, AE2, and AE3 may have a stacked structure such as ITO/Ag/ITO/, ITO/Ag/IZO, or ITO/Ag/ITZO/IZO.

A sacrificial layer SFL may be disposed on the first to third pixel electrodes AE1, AE2, and AE3. The sacrificial layer SFL may be disposed between upper surfaces of the first to third pixel electrodes AE1, AE2, and AE3 and the first insulating layer IL1. The sacrificial layer SFL may include an oxide semiconductor. In an embodiment, the sacrificial layer SFL may include at least one of indium gallium zinc oxide (“IGZO”), zinc tin oxide (“ZTO”), and indium tin oxide (“IZO”), for example.

The first insulating layer IL1 may be disposed on the thin film transistor layer TFTL and the sacrificial layer SFL. The first insulating layer IL1 may include an inorganic insulating material. The first insulating layer IL1 may include at least one of a silicon nitride layer, a silicon oxynitride layer, a silicon oxide layer, a titanium oxide layer, an aluminum oxide layer, and an amorphous silicon layer, but is not limited thereto.

The first bank BNK1 may be disposed on the first insulating layer IL1, the second bank BNK2 may be disposed on the first bank BNK1, and a bank material BKM may be disposed on the second bank BNK2.

The first bank BNK1 may include a metal material having relatively high electrical conductivity. The first bank BNK1 may include a copper (Cu) alloy. In an embodiment, the copper (Cu) alloy may be copper-magnesium-aluminum (CuMgAl), for example, but is not limited thereto. A composition ratio of copper (Cu) in copper-magnesium-aluminum (CuMgAl) may be about 90 at % or more, and a composition ratio of magnesium-aluminum (MgAl) in copper-magnesium-aluminum (CuMgAl) may be about 10 at % or less, but the disclosure is not limited thereto. Preferably, the composition ratio of copper (Cu) in copper-magnesium-aluminum (CuMgAl) may be about 90 at %, a composition ratio of magnesium (Mg) in copper-magnesium-aluminum (CuMgAl) may be about 3 at %, and a composition ratio of aluminum (Al) in copper-magnesium-aluminum (CuMgAl) may be about 7 at %. A composition ratio of copper-magnesium-aluminum (CuMgAl) may be easily designed and changed in order to prevent formation of an oxide film on a side surface or to enhance an adhesive force. Since the first bank BNK1 includes the copper (Cu) alloy, an adhesive force between the first bank BNK1 and the first insulating layer IL1 may be enhanced, such that a separate barrier layer may not be desired.

The bank material BKM may include a copper (Cu) alloy or pure copper. In an embodiment, the copper (Cu) alloy may be copper-magnesium-aluminum (CuMgAl), for example, but is not limited thereto.

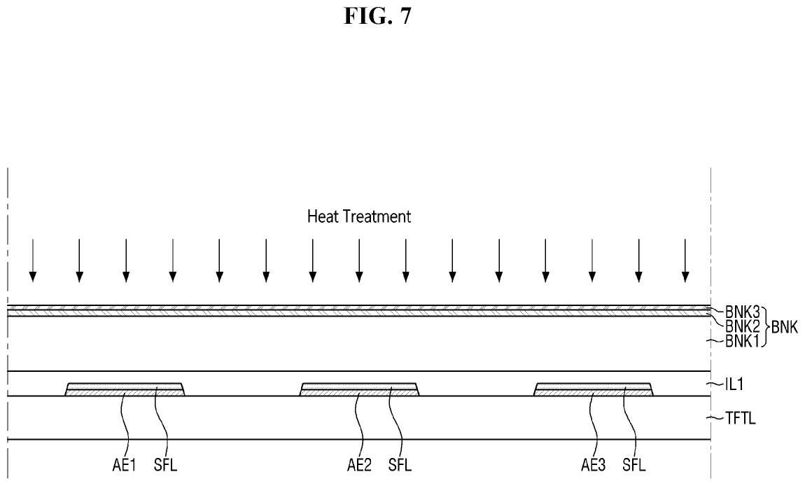

In FIG. 7, the bank material BKM disposed on an entirety of the surface of the display device 10 may be oxidized through a heat treatment process. The bank material BKM may be oxidized and changed into the third bank BNK3 having relatively low reflection characteristics. In an embodiment, when the bank material BKM includes a copper (Cu) alloy, the bank material BKM may be oxidized and changed into copper (Cu) alloy oxide. When the bank material BKM includes copper-magnesium-aluminum (CuMgAl), the bank material BKM may be oxidized and changed into copper-magnesium-aluminum oxide (CuMgAlOₓ) In another embodiment, when the bank material BKM includes pure copper, the bank material BKM may be oxidized and changed into copper oxide (CuOₓ).

The second bank BNK2 may include a metal material having relatively high thermal blocking performance. The second bank BNK2 may include titanium (Ti), but is not limited thereto. The second bank BNK2 may block heat from being transferred to the first bank BNK1 in a heat treatment process of the bank material BKM to prevent the first bank BNK1 from being oxidized.

The thickness of the first bank BNK1 may be greater than that of the third bank BNK3, and the thickness of the third bank BNK3 may be greater than that of the second bank BNK2. The thickness of the first bank BNK1 may be about 6000 Å, the thickness of the second bank BNK2 may be about 200 Å, and the thickness of the third bank BNK3 may be about 400 Å to about 500 Å, but the disclosure is not limited thereto.

The display device 10 may have a relatively low reflectivity in a region of visible light (about 550 nm) by including the third bank BNK3 having relatively low reflection characteristics. Accordingly, the display device 10 may decrease external light reflectivity and improve display quality.

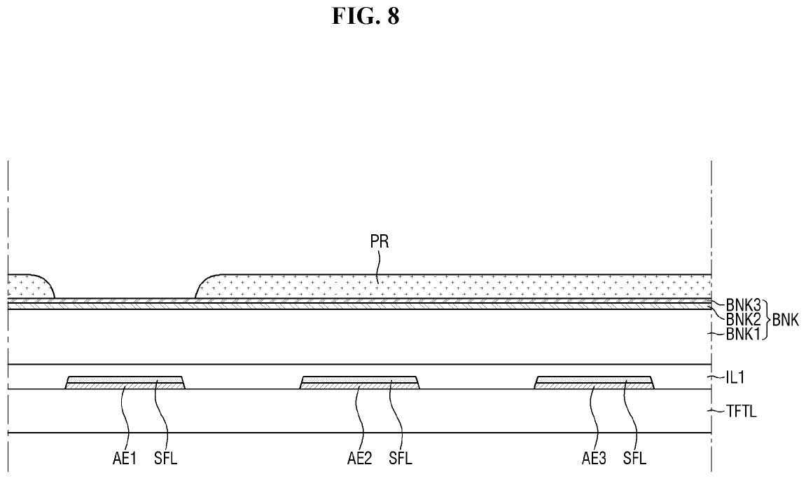

In FIG. 8, a photoresist PR may be disposed on the third bank BNK3 so as not to overlap the first pixel electrode AE1. The photoresist PR may be provided except for an area in which the first emission area EA1 is to be formed.

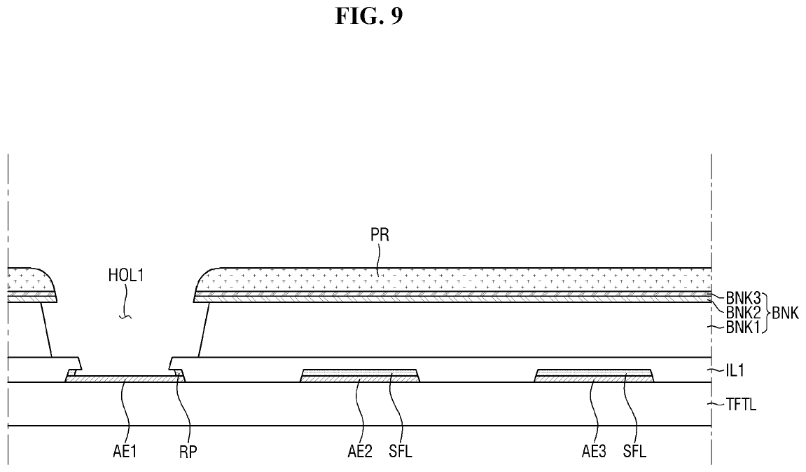

In FIG. 9, a first hole HOL1 may be defined by sequentially etching the bank BNK, the first insulating layer IL1, and the sacrificial layer SFL. The first hole HOL1 may overlap the first emission area EA1.

The bank BNK may be etched by performing at least one of a dry etching process and a wet etching process. In an embodiment, the bank BNK may be primarily etched through the dry etching process and secondarily etched through the wet etching process, for example, but is not limited thereto. The first bank BNK1 may include a metal material different than that of the second and third banks BNK2 and BNK3. An etch rate of the first bank BNK1 may be different from an etch rate of the second and third banks BNK2 and BNK3. In the wet etching process, the etch rate of the first bank BNK1 may be higher than the etch rate of the second and third banks BNK2 and BNK3, and the first bank BNK1 may be etched more than the second and third banks BNK2 and BNK3 Accordingly, shapes of the side surfaces of the first to third banks BNK1, BNK2, and BNK3 may be determined by a difference between the etch rates of the first to third banks BNK1, BNK2, and BNK3. The second bank BNK2 may include a tip protruding from the first bank BNK1 toward the first hole HOL1. The side surface of the first bank BNK1 may have a shape in which it is recessed inward from the side surface of the second bank BNK2. A lower portion of the tip of the second bank BNK2 may have an undercut structure. A thickness of the first bank BNK1 may be greater than that of the second bank BNK2. Since the first bank BNK1 is etched after the heat treatment process of the third bank BNK3, it is possible to prevent an oxide film from being formed on the side surface of the first bank BNK1, and electrical conductivity of the first bank BNK1 may be stably maintained.

The first insulating layer IL1 and the sacrificial layer SFL may be etched by performing at least one of a dry etching process and a wet etching process. In an embodiment, the first insulating layer IL1 may be etched through the dry etching process, and the sacrificial layer SFL may be etched through the wet etching process, for example, but the disclosure is not limited thereto. The first insulating layer IL1 and the sacrificial layer SFL are etched, such that at least a portion of an upper surface of the first pixel electrode AE1 may be exposed. In the wet etching process, the sacrificial layer SFL may be etched more than the first insulating layer IL1 in a plan view: When the sacrificial layer SFL is etched, the residual pattern RP may remain between the first insulating layer IL1 and the first pixel electrode AE1. Accordingly, a side surface of the residual pattern RP may have a shape in which it is recessed inward from a side surface of the first insulating layer IL1.

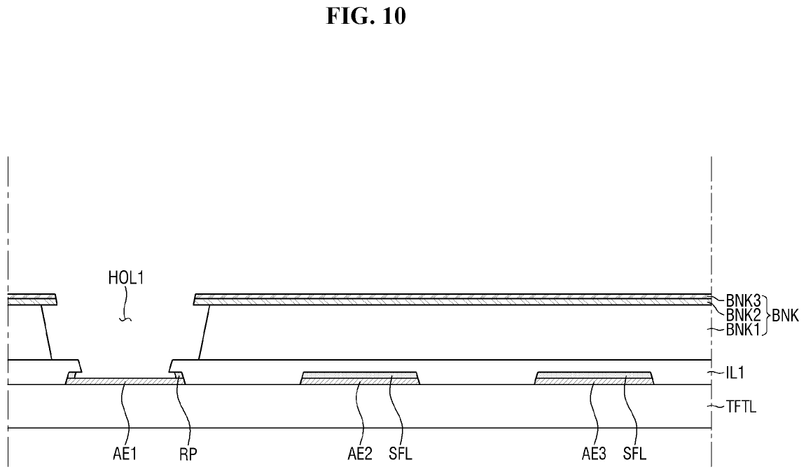

In FIG. 10, the photoresist PR may be removed through a strip process after the first hole HOL1 is defined.

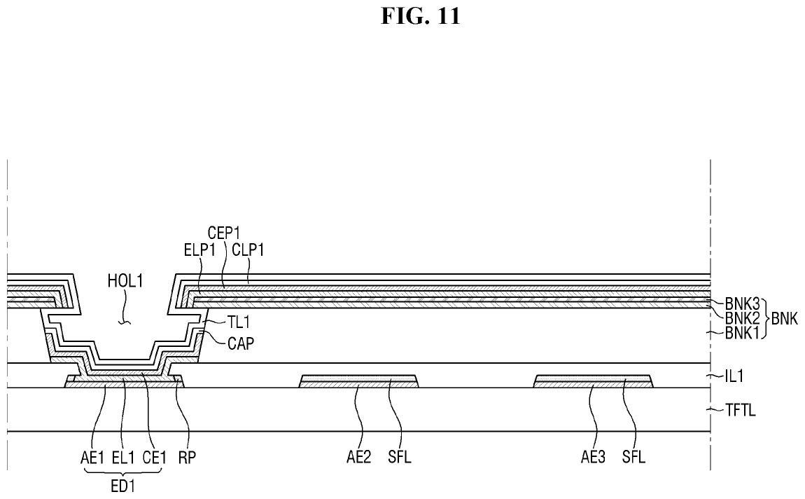

In FIG. 11, the first light-emitting layer EL1 may be directly disposed on the first pixel electrode AE1 in the first emission area EA1. A portion of the first light-emitting layer EL1 may be filled in a space surrounded by the first pixel electrode AE1, the residual pattern RP, and the first insulating layer IL1, and an opposite portion of the first light-emitting layer EL1 may cover a portion of an upper surface and side surfaces of the first insulating layer IL1.

An organic material for forming the first light-emitting layer EL1 and the first organic pattern ELP1 may be deposited on the entirety of the surface of the display device 10. The first organic pattern ELP1 may include the same organic material as that of the first light-emitting layer EL1 and may be disposed on the third bank BNK3. The first organic pattern ELP1 may cover side surfaces of the second and third banks BNK2 and BNK3 adjacent to the first emission area EA1. The first light-emitting layer EL1 and the first organic pattern ELP1 may be deposited in the same process, but may be cut by the tip formed on the inner sidewall of the bank BNK. Accordingly, the first organic pattern ELP1 may be disposed on the third bank BNK3 in an area other than the first emission area EA1.

The first common electrode CE1 may be disposed on the first light-emitting layer EL1. The first common electrode CE1 may include a transparent conductive material and may transmit light generated in the first light-emitting layer EL1 therethrough. The first common electrode CE1 may contact the side surfaces of the first bank BNK1. Accordingly, the first light-emitting element ED1 may be formed in the first hole HOL1 and may emit the light through the first emission area EA1.

A metal material for forming the first common electrode CE1 and the first electrode pattern CEP1 may be deposited on the entirety of the surface of the display device 10. The first electrode pattern CEP1 may include the same metal material as that of the first common electrode CE1 and may be disposed on the first organic pattern ELP1. The first electrode pattern CEP1 may cover side surfaces of the first organic pattern ELP1 adjacent to the first emission area EA1. The first common electrode CE1 and the first electrode pattern CEP1 may be deposited in the same process, but may be cut by the tip formed on the inner sidewall of the bank BNK. Accordingly, the first electrode pattern CEP1 may be disposed on the first organic pattern ELP1 in the area other than the first emission area EA1.

The capping layer CAP may be disposed on the first common electrode CE1. The capping layer CAP may include an inorganic insulating material and may cover the first light-emitting element ED1. The capping layer CAP may prevent the first light-emitting element ED1 from being damaged by external air. In an embodiment, the capping layer CAP may include at least one of a silicon nitride layer, a silicon oxynitride layer, a silicon oxide layer, a titanium oxide layer, an aluminum oxide layer, and an amorphous silicon layer, for example, but is not limited thereto.

An inorganic material for forming the capping layer CAP and the first capping pattern CLP1 may be deposited on the entirety of the surface of the display device 10. The first capping pattern CLP1 may include the same inorganic material as that of the capping layer CAP and may be disposed on the first electrode pattern CEP1. The first capping pattern CLP1 may cover side surfaces of the first electrode pattern CEP1 adjacent to the first emission area EA1. The capping layer CAP and the first capping pattern CLP1 may be deposited in the same process, but may be cut by the tip formed on the inner sidewall of the bank BNK. Accordingly, the first capping pattern CLP1 may be disposed on the first electrode pattern CEP1 in the area other than the first emission area EA1.

The first inorganic layer TL1 may be disposed on the capping layer CAP of the first emission area EA1 and the first capping pattern CLP1. The first inorganic layer TL1 may cover the side surfaces of the first bank BNK1 surrounding the first emission area EA1. The first inorganic layer TL1 may include an inorganic material to prevent oxygen or moisture from permeating into the first light-emitting element ED1. The first inorganic layer TL1 may be an inorganic encapsulation layer. In an embodiment, the first inorganic layer TL1 may include at least one of a silicon nitride layer, a silicon oxynitride layer, a silicon oxide layer, a titanium oxide layer, an aluminum oxide layer, and an amorphous silicon layer, for example, but is not limited thereto.

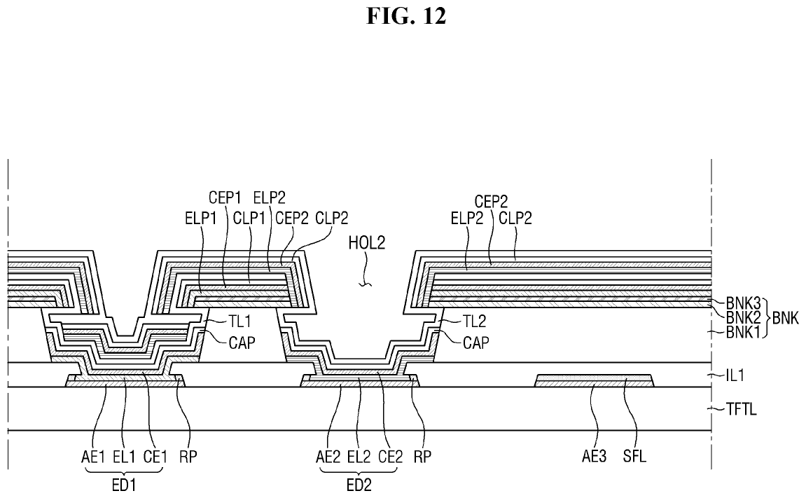

In FIG. 12, a second hole HOL2 may overlap the second emission area EA2. The second hole HOL2 may be defined by sequentially etching the first inorganic layer TL1, the first capping pattern CLP1, the first electrode pattern CEP1, the first organic pattern ELP1, the bank BNK, the first insulating layer IL1, and the sacrificial layer SFL. In a process of forming the second hole HOL2, the bank BNK, the first insulating layer IL1, and the sacrificial layer SFL may be etched in substantially the same manner as the processes described above with reference to FIGS. 8 to 10.

The second light-emitting layer EL2 may be directly disposed on the second pixel electrode AE2 in the second emission area EA2. A portion of the second light-emitting layer EL2 may be filled in a space surrounded by the second pixel electrode AE2, the residual pattern RP, and the first insulating layer IL1, and an opposite portion of the second light-emitting layer EL2 may cover a portion of an upper surface and side surfaces of the first insulating layer IL1.

An organic material for forming the second light-emitting layer EL2 and the second organic pattern ELP2 may be deposited on the entirety of the surface of the display device 10. The second organic pattern ELP2 may include the same organic material as that of the second light-emitting layer EL2 and may be disposed on the first inorganic layer TL1. The second organic pattern ELP2 may cover side surfaces of the second and third banks BNK2 and BNK3, the first organic pattern ELP1, the first electrode pattern CEP1, the first capping pattern CLP1, and the first inorganic layer TL1 adjacent to the second emission area EA2. The second light-emitting layer EL2 and the second organic pattern ELP2 may be deposited in the same process, but may be cut by the tip formed on the inner sidewall of the bank BNK. Accordingly, the second organic pattern ELP2 may be disposed on the first inorganic layer TL1 in an area other than the second emission area EA2.

The second common electrode CE2 may be disposed on the second light-emitting layer EL2. The second common electrode CE2 may include a transparent conductive material and may transmit light generated in the second light-emitting layer EL2 therethrough. The second common electrode CE2 may contact the side surfaces of the first bank BNK1. Accordingly, the second light-emitting element ED2 may be formed in the second hole HOL2 and may emit the light through the second emission area EA2.

A metal material for forming the second common electrode CE2 and the second electrode pattern CEP2 may be deposited on the entirety of the surface of the display device 10. The second electrode pattern CEP2 may include the same metal material as that of the second common electrode CE2 and may be disposed on the second organic pattern ELP2. The second electrode pattern CEP2 may cover side surfaces of the second organic pattern ELP2 adjacent to the second emission area EA2. The second common electrode CE2 and the second electrode pattern CEP2 may be deposited in the same process, but may be cut by the tip formed on the inner sidewall of the bank BNK. Accordingly, the second electrode pattern CEP2 may be disposed on the second organic pattern ELP2 in the area other than the second emission area EA2.

The capping layer CAP may be disposed on the second common electrode CE2. The capping layer CAP may include an inorganic insulating material and may cover the second light-emitting element ED2. The capping layer CAP may prevent the second light-emitting element ED2 from being damaged by external air.

An inorganic material for forming the capping layer CAP and the second capping pattern CLP2 may be deposited on the entirety of the surface of the display device 10. The second capping pattern CLP2 may include the same inorganic material as that of the capping layer CAP and may be disposed on the second electrode pattern CEP2. The second capping pattern CLP2 may cover side surfaces of the second electrode pattern CEP2 adjacent to the second emission area EA2. The capping layer CAP and the second capping pattern CLP2 may be deposited in the same process, but may be cut by the tip formed on the inner sidewall of the bank BNK. Accordingly, the second capping pattern CLP2 may be disposed on the second electrode pattern CEP2 in the area other than the second emission area EA2.

The second inorganic layer TL2 may be disposed on the capping layer CAP of the second emission area EA2 and the second capping pattern CLP2. The second inorganic layer TL2 may cover the side surfaces of the first bank BNK1 surrounding the second emission area EA2. The second inorganic layer TL2 may include an inorganic material to prevent oxygen or moisture from permeating into the second light-emitting element ED2. The second inorganic layer TL2 may be an inorganic encapsulation layer. In an embodiment, the second inorganic layer TL2 may include or consist of the material exemplified in the first inorganic layer TL1, for example.

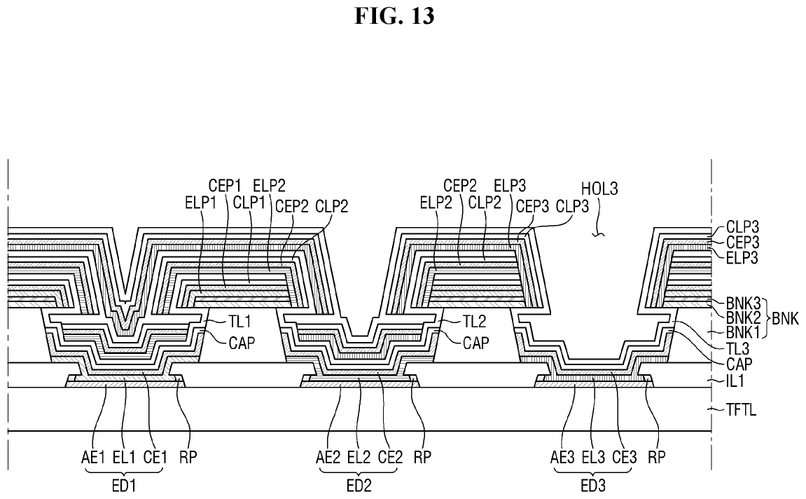

In FIG. 13, a third hole HOL3 may overlap the third emission area EA3. The third hole HOL3 may be formed by sequentially etching the second inorganic layer TL2, the second capping pattern CLP2, the second electrode pattern CEP2, the second organic pattern ELP2, the first inorganic layer TL1, the first capping pattern CLP1, the first electrode pattern CEP1, the first organic pattern ELP1, the bank BNK, the first insulating layer IL1, and the sacrificial layer SFL. In a process of forming the third hole HOL3, the bank BNK, the first insulating layer IL1, and the sacrificial layer SFL may be etched in substantially the same manner as the processes described above with reference to FIGS. 8 to 10.

The third light-emitting layer EL3 may be directly disposed on the third pixel electrode AE3 in the third emission area EA3. A portion of the third light-emitting layer EL3 may be filled in a space surrounded by the third pixel electrode AE3, the residual pattern RP, and the first insulating layer IL1, and an opposite portion of the third light-emitting layer EL3 may cover a portion of an upper surface and side surfaces of the first insulating layer IL1.

An organic material for forming the third light-emitting layer EL3 and the third organic pattern ELP3 may be deposited on the entirety of the surface of the display device 10. The third organic pattern ELP3 may include the same organic material as that of the third light-emitting layer EL3 and may be disposed on the second inorganic layer TL2. The third organic pattern ELP3 may cover side surfaces of the second and third banks BNK2 and BNK3, the first organic pattern ELP1, the first electrode pattern CEP1, the first capping pattern CLP1, the first inorganic layer TL1, the second organic pattern ELP2, the second electrode pattern CEP2, the second capping pattern CLP2, and the second inorganic layer TL2 adjacent to the third emission area EA3. The third light-emitting layer EL3 and the third organic pattern ELP3 may be deposited in the same process, but may be cut by the tip formed on the inner sidewall of the bank BNK. Accordingly, the third organic pattern ELP3 may be disposed on the second inorganic layer TL2 in an area other than the third emission area EA3.

The third common electrode CE3 may be disposed on the third light-emitting layer EL3. The third common electrode CE3 may include a transparent conductive material and may transmit light generated in the third light-emitting layer EL3 therethrough. The third common electrode CE3 may contact the side surfaces of the first bank BNK1. Accordingly, the third light-emitting element ED3 may be formed in the third hole HOL3 and may emit the light through the third emission area EA3.

A metal material for forming the third common electrode CE3 and the third electrode pattern CEP3 may be deposited on the entirety of the surface of the display device 10. The third electrode pattern CEP3 may include the same metal material as that of the third common electrode CE3 and may be disposed on the third organic pattern ELP3. The third electrode pattern CEP3 may cover side surfaces of the third organic pattern ELP3 adjacent to the third emission area EA3. The third common electrode CE3 and the third electrode pattern CEP3 may be deposited in the same process, but may be cut by the tip formed on the inner sidewall of the bank BNK. Accordingly, the third electrode pattern CEP3 may be disposed on the third organic pattern ELP3 in the area other than the third emission area EA3. The capping layer CAP may be disposed on the third common electrode CE3. The capping layer CAP may include an inorganic insulating material and may cover the third light-emitting element ED3. The capping layer CAP may prevent the third light-emitting element ED3 from being damaged by external air.

An inorganic material for forming the capping layer CAP and the third capping pattern CLP3 may be deposited on the entirety of the surface of the display device 10. The third capping pattern CLP3 may include the same inorganic material as that of the capping layer CAP and may be disposed on the third electrode pattern CEP3. The third capping pattern CLP3 may cover side surfaces of the third electrode pattern CEP3 adjacent to the third emission area EA3. The capping layer CAP and the third capping pattern CLP3 may be deposited in the same process, but may be cut by the tip formed on the inner sidewall of the bank BNK. Accordingly, the third capping pattern CLP3 may be disposed on the third electrode pattern CEP3 in the area other than the third emission area EA3.

The third inorganic layer TL3 may be disposed on the capping layer CAP of the third emission area EA3 and the third capping pattern CLP3. The third inorganic layer TL3 may cover the side surfaces of the first bank BNK1 surrounding the third emission area EA3.

The third inorganic layer TL3 may include an inorganic material to prevent oxygen or moisture from permeating into the third light-emitting element ED3. The third inorganic layer TL3 may be an inorganic encapsulation layer. In an embodiment, the third inorganic layer TL3 may include or consist of the material exemplified in the first inorganic layer TL1, for example.

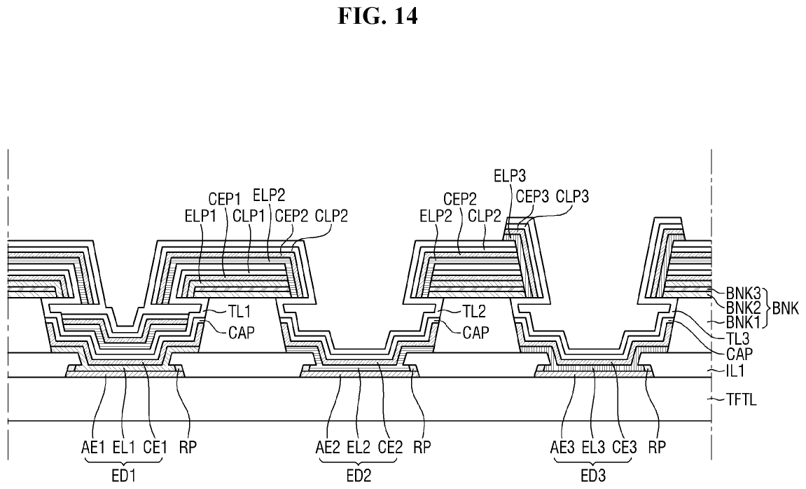

In FIG. 14, the third inorganic layer TL3, the third capping pattern CLP3, the third electrode pattern CEP3, and the third organic pattern ELP3 may be sequentially etched in the first emission area EA1 and an area adjacent to the first emission area EA1 and the second emission area EA2 and an area adjacent to the second emission area EA2. The third inorganic layer TL3, the third capping pattern CLP3, the third electrode pattern CEP3, and the third organic pattern ELP3 may remain in an area adjacent to the third emission area EA3. The third inorganic layer TL3, the third capping pattern CLP3, the third electrode pattern CEP3, and the third organic pattern ELP3 may be etched by performing at least one of a dry etching process and a wet etching process.

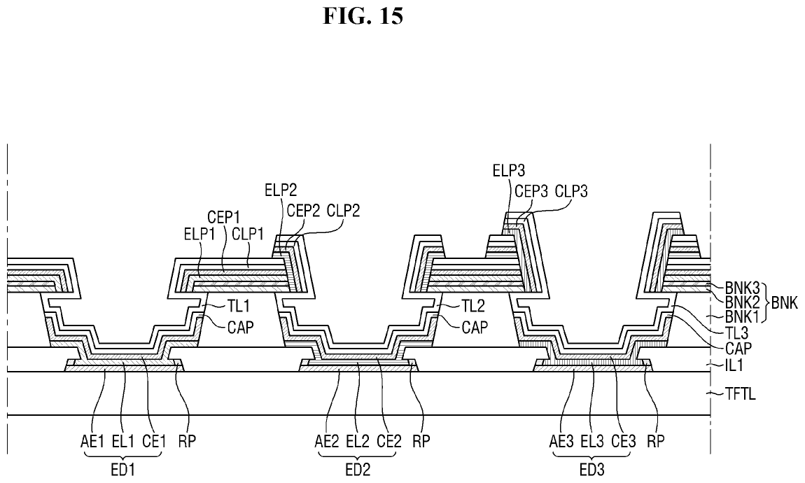

In FIG. 15, the second inorganic layer TL2, the second capping pattern CLP2, the second electrode pattern CEP2, and the second organic pattern ELP2 may be sequentially etched in the first emission area EA1 and an area adjacent to the first emission area EA1. The second inorganic layer TL2, the second capping pattern CLP2, the second electrode pattern CEP2, and the second organic pattern ELP2 may remain in an area adjacent to the second emission area EA2. The second inorganic layer TL2, the second capping pattern CLP2, the second electrode pattern CEP2, and the second organic pattern ELP2 may be etched by performing at least one of a dry etching process and a wet etching process.

What is claimed is:

1. A display device comprising:
a first pixel electrode disposed in a first emission area on a substrate;
an insulating layer covering an edge of the first pixel electrode;
a first light-emitting layer disposed on the first pixel electrode and the insulating layer;
a first common electrode disposed on the first light-emitting layer;
a bank disposed on the insulating layer and surrounding the first emission area;
a first organic pattern surrounding the first emission area on the bank and including a same material as a material of the first light-emitting layer; and
a first electrode pattern surrounding the first emission area on the first organic pattern and including a same material as a material of the first common electrode,
wherein the bank comprises:
a first bank disposed on the insulating layer and in contact with the first common electrode;
a second bank which is disposed on the first bank and including a tip structure protruding toward the first emission area and separates the first common electrode and the first electrode pattern from each other; and
a third bank disposed on the second bank and having relatively low reflection characteristics.

2. The display device of claim 1, wherein the third bank includes copper (Cu) alloy oxide or copper oxide (CuOₓ).

3. The display device of claim 2, wherein the copper (Cu) alloy oxide includes copper-magnesium-aluminum oxide (CuMgAlOₓ).

4. The display device of claim 1, wherein the first bank includes a copper (Cu) alloy, and the second bank includes titanium (Ti).

5. The display device of claim 4, wherein the copper (Cu) alloy includes copper-magnesium-aluminum (CuMgAl).

6. The display device of claim 5, wherein a composition ratio of copper (Cu) in the copper-magnesium-aluminum (CuMgAl) is 90 at % or more.

7. The display device of claim 1, wherein a side surface of the first bank is recessed inward from a side surface of the second bank.

8. The display device of claim 1, further comprising:
a second pixel electrode disposed in a second emission area on the substrate;
a second light-emitting layer disposed on the second pixel electrode; and
a second common electrode disposed on the second light-emitting layer.

9. The display device of claim 8, wherein the first and second common electrodes are electrically connected to each other through the first bank.

10. The display device of claim 8, further comprising:
a second organic pattern surrounding the second emission area on the first electrode pattern and including a same material as a material of the second light-emitting layer; and
a second electrode pattern surrounding the second emission area on the second organic pattern and including a same material as a material of the second common electrode.

11. A method of manufacturing a display device, the method comprising:
forming first and second pixel electrodes on a substrate;
stacking a sacrificial layer, an insulating layer, a first bank, a second bank, and a bank material on the first and second pixel electrodes;
forming a third bank having relatively low reflection characteristics by performing a heat treatment process on the bank material;
etching the third bank, the second bank, and the first bank so that a side surface of the second bank includes a tip structure protruding from a side surface of the first bank;
exposing the first pixel electrode by etching the insulating layer and the sacrificial layer; and
forming a first light-emitting layer on the first pixel electrode and forming a first organic pattern on the third bank.

12. The method of manufacturing a display device of claim 11, wherein the bank material includes a copper (Cu) alloy, and the copper (Cu) alloy is oxidized and changed into copper (Cu) alloy oxide through the heat treatment process.

13. The method of manufacturing a display device of claim 11, wherein the bank material includes pure copper, and the pure copper is oxidized and changed into copper oxide (CuOₓ) through the heat treatment process.

14. The method of manufacturing a display device of claim 11, wherein the first bank includes a copper (Cu) alloy, and the second bank includes titanium (Ti).

15. The method of manufacturing a display device of claim 14, wherein the copper (Cu) alloy is copper-magnesium-aluminum (CuMgAl), and a composition ratio of copper (Cu) in the copper-magnesium-aluminum (CuMgAl) is 90 at % or more.

16. The method of manufacturing a display device of claim 11, wherein the etching the third bank, the second bank, and the first bank comprises etching the side surface of the first bank more than the side surface of the second bank to form the tip structure of the second bank.

17. The method of manufacturing a display device of claim 11, wherein the forming the first light-emitting layer and the first organic pattern comprises cutting an organic material deposited on the substrate by a tip of the second bank to separate the organic material into the first light-emitting layer and the first organic pattern.

18. The method of manufacturing a display device of claim 11, further comprising:
forming a first common electrode on the first light-emitting layer and forming a first electrode pattern on the first organic pattern; and
forming a capping layer on the first common electrode and forming a first capping pattern on the first electrode pattern.

19. The method of manufacturing a display device of claim 18, wherein the forming the first common electrode and the first electrode pattern comprises cutting a metal material deposited on the substrate by a tip of the second bank to separate the metal material into the first common electrode and the first electrode pattern.

20. The method of manufacturing a display device of claim 18, wherein the forming the capping layer and the first capping pattern comprises cutting an inorganic material deposited on the substrate by a tip of the second bank to separate the inorganic material into the capping layer and the first capping pattern.
